(19) United States
(12) Patent Application Publication
(10) Pub. No.: US 2026/0280565 A1
(43) Pub. Date: Sep. 17, 2026

(54) LEVEL SHIFT CIRCUIT AND LEVEL SHIFT METHOD

(71) Applicant: Nuvoton Technology Corporation Japan, Kyoto (JP)

(72) Inventor: Shigeyuki HAYAKAWA, Kyoto (JP)

(21) Appl. No.: 19/684,228

(22) Filed: May 21, 2026

Related U.S. Application Data
(63) Continuation of application No. PCT/JP2024/042628, filed on Dec. 3, 2024.

(30) Foreign Application Priority Data
Dec. 5, 2023 (JP) 2023-205174

(51) Int. Cl. H03K 19/0185; H03K 3/037

(52) U.S. Cl. CPC H03K 19/018521; H03K 3/037

(57) ABSTRACT

A level shift circuit includes: an input circuit that converts an input signal into a pair of complementary first signals, the input signal being generated using a first voltage source as a power source; a precharge circuit that outputs a pair of second signals from a first node and a second node, the pair of second signals corresponding to the pair of complementary first signals; and a precharge control circuit that outputs a pair of third signals and controls the precharge circuit, based on the pair of second signals. The input circuit includes a first phase alignment circuit that adjusts phases of the pair of complementary first signals to be substantially.

### DESCRIPTION

### CROSS REFERENCE TO RELATED APPLICATIONS

This is a continuation application of PCT International Patent Application No. PCT/JP2024/042628 filed on December 3, 2024, designating the United States of America, which is based on and claims priority of Japanese Patent Application No. 2023-205174 filed on December 5, 2023. The entire disclosures of the above-identified applications, including the specifications, drawings and claims are incorporated herein by reference in their entirety.

### FIELD

The present disclosure relates to level shift circuits and level shift methods that shift a logic level.

### BACKGROUND

Conventionally, various circuits have been proposed as level shift circuits (see, for example, Patent Literatures (PTLS) 1 and 2). In the technique disclosed in PTL 1, by providing a phase alignment circuit in an output stage of a level shift circuit, variations in the duty cycle of an output signal relative to the duty cycle of an input signal due to changes in temperature, power supply voltage, manufacturing processes, etc. are suppressed. It should be noted that the phrase “variations in the duty cycle of an output signal relative to the duty cycle of an input signal” means a phenomenon in which the duty cycle of the input signal and the duty cycle of the output signal do not match.

### Citation List

### Patent Literature

PTL 1: Japanese Unexamined Patent Application Publication No. 2000-305528

PTL 2: Japanese Unexamined Patent Application Publication No. 2004-7821

### SUMMARY

### Technical Problem

In the technique disclosed in PTL 1, however, a pair of complementary input signals is required as an input of the level shift circuit. It should be noted that a pair of complementary signals refer to signals that are logical inverses of each other (Hi/Lo).

In contrast, in the technique disclosed in PTL 2, a level shift circuit that receives a single-ended signal as an input and shifts a logic level is proposed. In the technique disclosed in PTL 2, however, although a pair of complementary signals is generated from a single-ended signal in an input stage, the duty cycle of an output signal varies relative to the duty cycle of an input signal due to changes in temperature, power supply voltage, manufacturing processes, etc.

In view of the above, the present disclosure provides a level shift circuit and a level shift method that make it possible to receive a single-ended signal as an input and suppress variations in the duty cycle of an output signal relative to the duty cycle of an input signal.

### Solution to Problem

In order to solve the above problem, a level shift circuit according to one aspect of the present disclosure is a level shift circuit that shifts a logic level, and includes: an input circuit that converts an input signal into a pair of complementary first signals, the input signal being generated using a first voltage source as a power source; a precharge circuit that includes a first node, a second node, a first transistor, and a second transistor, and outputs a pair of second signals corresponding to the pair of complementary first signals from the first node and the second node after precharging the first node and the second node to an electric potential of a second voltage source, the pair of complementary first signals outputted from the input circuit being inputted to the first transistor and the second transistor; and a precharge control circuit that outputs a pair of third signals and controls the precharge circuit, based on the pair of second signals outputted from the precharge circuit. The input circuit includes a first phase alignment circuit that adjusts phases of the pair of complementary first signals to be substantially aligned. In order to solve the above problem, a level shift method according to one aspect of the present disclosure is a level shift method that shifts a logic level, and includes: converting an input signal into a pair of complementary first signals, the input signal being generated using a first voltage source as a power source; outputting a pair of second signals corresponding to the pair of complementary first signals from a first node and a second node after precharging the first node and the second node to an electric potential of a second voltage source, the first node and the second node being included in a precharge circuit; outputting a pair of third signals and controlling the precharge circuit, based on the pair of second signals outputted in the outputting of the pair of second signals; and adjusting phases of the pair of complementary first signals and/or the pair of third signals to be substantially aligned.

### Advantageous Effects

The present disclosure provides a level shift circuit and a level shift method that make it possible to receive a single-ended signal as an input and suppress variations in the duty cycle of an output signal relative to the duty cycle of an input signal.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a circuit diagram showing a level shift circuit according to an embodiment.

FIG. 2 is a timing chart showing an operation example of the level shift circuit according to the embodiment.

FIG. 3 is a circuit diagram showing a level shift circuit according to Variation 1 of the embodiment.

FIG. 4 is a circuit diagram showing a level shift circuit according to Variation 2 of the embodiment.

FIG. 5 is a block diagram showing a configuration of a level shift circuit according to Technique 1 of the embodiment.

FIG. 6 is a block diagram showing a configuration of a level shift circuit according to Technique 2 of the embodiment.

FIG. 7 is a block diagram showing a configuration of a level shift circuit according to Technique 3 of the embodiment.

FIG. 8 is a block diagram showing a configuration of a level shift circuit according to Technique 4 of the embodiment.

FIG. 9 is a block diagram showing a configuration of a level shift circuit according to Technique 5 of the embodiment.

FIG. 10 is a block diagram showing a configuration of a level shift circuit according to Technique 6 of the embodiment.

### DESCRIPTION OF EMBODIMENT

Hereinafter, an embodiment of the present disclosure is described in detail with reference to the Drawing. It should be noted that the embodiment described blow shows a specific example of the present disclosure. The numerical values, circuit elements, the connection between the circuit elements, signal waveforms, timings, etc. shown in the following embodiment are mere examples, and are not intended to limit the present disclosure. In addition, each of the figures is not necessarily a precise illustration. In each figure, the same reference signs are assigned to substantially the same constituent elements, and redundant portions of the description are omitted or simplified. Additionally, “A and B are connected” means that A and B are electrically connected, and includes not only a case in which A and B are directly connected but also a case in which A and B are indirectly connected via another circuit element interposed between A and B.

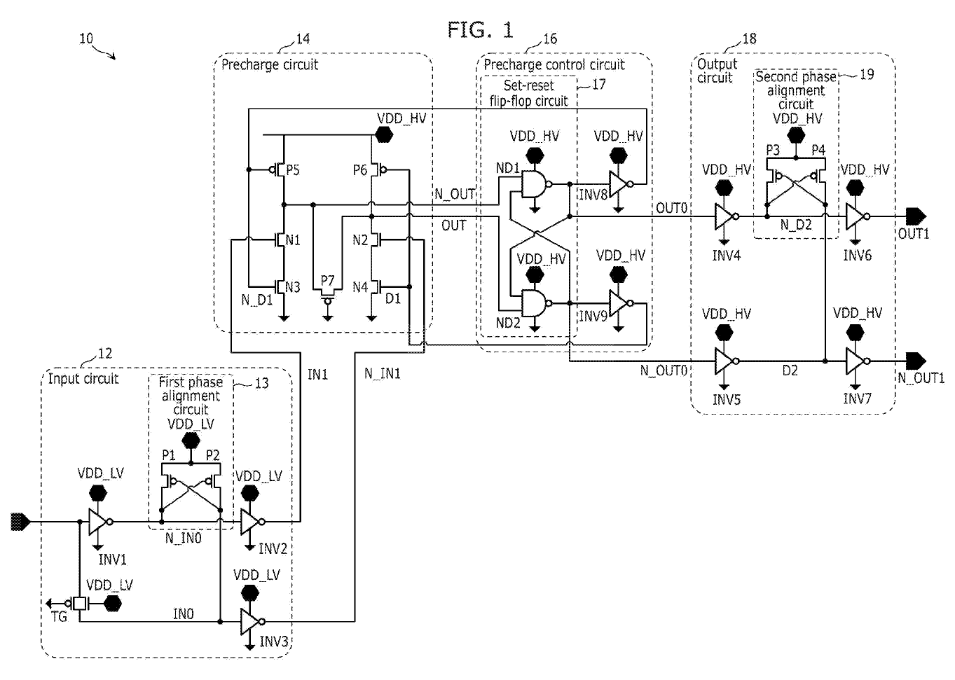

FIG. 1 is a circuit diagram showing level shift circuit 10 according to the embodiment. Level shift circuit 10 is a circuit that shifts a logic level (here a voltage having a Hi level), and includes input circuit 12, precharge circuit 14, precharge control circuit 16, and output circuit 18.

Input circuit 12 is a circuit that converts single-ended signal IN (i.e., an input signal generated using, as a power source, first voltage source VDD_LV that is a low-voltage source) inputted from input terminal IN into a pair of complementary first signals IN1 and N_IN1, and includes first phase alignment circuit 13 for adjusting the phases of the pair of complementary first signals IN1 and N_IN1 to be substantially aligned. It should be noted that the reference sign “IN” is used not only as a reference sign for an input terminal but also as a reference sign for a single-ended signal inputted to input terminal IN. The reference sign “VDD_LV” is used not only as a reference sign for the first voltage source but also as a reference sign for a first voltage supplied by first voltage source VDD_LV as described below.

Precharge circuit 14 includes at least first node N_OUT and second node OUT that are output terminals, and a first N-type MOSFET (N1) and a second N-type MOSFET (N2) that are examples of a first transistor and a second transistor into which the pair of complementary first signals IN1 and N_IN1 outputted from input circuit 12 is inputted. After precharging first node N_OUT and second node OUT to an electric potential of second voltage source VDD_HV that is a high-voltage source, precharge circuit 14 outputs, from first node N_OUT and second node OUT, a pair of second signals N_OUT and OUT corresponding to the pair of complementary first signals IN1 and N_IN1.

The reference sign “VDD_HV” is used not only as a reference sign for the second voltage source but also as a reference sign for a second voltage supplied by second voltage source VDD_HV as described below. Additionally, the reference signs “N_OUT” and “OUT” are used not only as reference signs for the first node and the second, respectively, but also as reference signs for a signal (second signal N_OUT) at first node N_OUT and a signal (second signal OUT) at second node OUT, respectively.

Based on the pair of second signals N_OUT and OUT outputted from precharge circuit 14, precharge control circuit 16 outputs a pair of third signals OUT0 and N_OUT0, generates a pair of fifth signals N_D1 and D1, and controls precharge circuit 14.

Output circuit 18 is a circuit that outputs a pair of complementary fourth signals OUT1 and N_OUT1, based on the pair of third signals OUT0 and N_OUT0 outputted from precharge control circuit 16, and includes second phase alignment circuit 19 for adjusting the phases of the pair of complementary fourth signals OUT1 and N_OUT 1 to be substantially aligned.

Hereinafter, detailed configurations of input circuit 12, precharge circuit 14, precharge control circuit 16, and output circuit 18 are described.

Input circuit 12 includes a two-or-more-stage inverter chain (here inverters INV1 and INV2) for generating the pair of complementary first signals IN1 and N_IN1 from single-ended signal IN inputted from input terminal IN, one-stage transfer gate TG, and a one-or-more-stage inverter chain (here inverter INV3). Inverter INV1 converts single-ended signal IN into inverted signal N_IN0 by applying logical inversion and a delay to single-ended signal IN, and inverter INV2 converts single-ended signal IN into complementary first signal IN1 by applying logical inversion and a delay to single-ended signal IN. Concurrently, transfer gate TG converts single-ended signal IN into delayed signal IN0 by applying a delay to single-ended signal IN, and inverter INV3 converts single-ended signal IN into complementary first signal N_IN1 by applying logical inversion and a delay to single-ended signal IN.

Moreover, input circuit 12 includes first phase alignment circuit 13 that adjusts the phases of the pair of complementary first signals IN1 and N_IN1 outputted from inverters INV2 and INV3 to be substantially aligned, by adjusting the phases of a pair of inverted signal N_IN0 and delayed signal IN0 to be substantially aligned. First phase alignment circuit 13 includes a first P-type MOSFET (P1) and a second P-type MOSFET (P2) that are cross-coupled. The source terminals of the first P-type MOSFET (P1) and the second P-type MOSFET (P2) are both connected to first voltage source VDD_LV. The gate terminal of the first P-type MOSFET (P1) is connected to the drain terminal of the second P-type MOSFET (P2), and the gate terminal of the second P-type MOSFET (P2) is connected to the drain terminal of the first P-type MOSFET (P1). The drain terminal of the first P-type MOSFET (p1) is connected to the input terminal of final-stage inverter INV2 included in the two-or-more-stage inverter chain (here inverters INV1 and INV2), and the drain terminal of the second P-type MOSFET (P2) is connected to the input terminal of final-stage inverter INV3 included in one-stage transfer gate TG and the one-or-more-stage inverter chain (here inverter INV3).

In the present embodiment, to output the pair of third signals OUT0 and N_OUT0 from first node N_OUT and second node OUT, based on the pair of complementary first signals IN1 and N_IN1 outputted from input circuit 12, precharge circuit 14 includes a third N-type MOSFET (N3),a fourth N-type MOSFET (N4), a fifth P-type MOSFET (P5), a sixth P-type MOSFET (P6), and a seventh P-type MOSFET (P7) in addition to the first N-type MOSFET (N1) and the second N-type MOSFET (N2) described above.

The gate terminal of the first N-type MOSFET (N1) is connected to the output terminal of final-stage inverter INV2 included in the two-or-more-stage inverter chain (here inverters INV1 and INV2) of input circuit 12, and the gate terminal of the second N-type MOSFET (N2) is connected to the output terminal of final-stage inverter INV3 included in one-stage transfer gate TG and one-or-more-stage inverter chain (here inverter INV3) of input circuit 12. The drain terminal of the first N-type MOSFET (N1) is connected to first node N_OUT, and the drain terminal of the second N-type MOSFET (N2) is connected to second node OUT.

The source terminals of the third N-type MOSFET (N3) and the fourth N-type MOSFET (N4) are both grounded. The drain terminal of the third N-type MOSFET (N3) is connected to the source terminal of the first N-type MOSFET (N1), and the drain terminal of the fourth N-type MOSFET (N4) is connected to the source terminal of the second N-type MOSFET (N2).

The source terminals of the fifth P-type MOSFET (P5) and the sixth P-type MOSFET (P6) are both connected to second voltage source VDD_HV. The drain terminal of the fifth P-type MOSFET (P5) is connected to the drain terminal of the first N-type MOSFET (N1), and the drain terminal of the sixth P-type MOSFET (P6) is connected to the drain terminal of the second N-type MOSFET (N2).

When fifth signal N_D1 outputted from precharge control circuit 16 is supplied to both the gate terminals of the fifth P-type MOSFET (P5) and the third N-type MOSFET (N3) that are complementary transistors, one of the fifth P-type MOSFET (P5) and the third N-type MOSFET (N3) turns ON and the other of the fifth P-type MOSFET (P5) and the third N-type MOSFET (N3) turns OFF, and a shoot-through current does not flow between second voltage source VDD_HV and a ground in this path. Similarly, when fifth signal D1 outputted from precharge control circuit 16 is supplied to both the gate terminals of the sixth P-type MOSFET (P6) and the fourth N-type MOSFET (N4) that are complementary transistors, one of the sixth P-type MOSFET (P6) and the fourth N-type MOSFET (N4) turns ON and the other of the sixth P-type MOSFET (P6) and the fourth N-type MOSFET (N4) turns OFF, and a shoot-through current does not flow between second voltage source VDD_HV and a ground in this path.

The drain terminal and the source terminal of the seventh P-type MOSFET (P7) are connected to first node N_OUT and second node OUT, respectively, and the gate terminal of the seventh P-type MOSFET (P7) is grounded. The seventh P-type MOSFET (P7) functions as a resistor and causes first node N_OUT and second node OUT not to be in a high impedance state by connecting second voltage source VDD_HV to first node N_OUT or second node OUT.

Precharge control circuit 16 incudes: set-reset flip-flop circuit 17 that includes first NAND circuit ND1 and second NAND circuit ND2; and two inverters INV8 and INV9 that receive outputs of first NAND circuit ND1 and second NAND circuit ND2, respectively, invert the outputs, and output the inverted outputs.

Two input terminals of set-reset flip-flop circuit 17 are connected to first node N_OUT and second node OUT of precharge circuit 14, respectively, and two output terminals of set-reset flip-flop circuit 17 are connected to two inverters INV8 and INV9, respectively. Two output terminals (i.e., the output terminals of two inverters INV8 and INV9) of precharge control circuit 16 are connected to (i) the gate terminals of the third N-type MOSFET (N3) and the fifth P-type MOSFET (P5) of precharge circuit 14 and (ii) the gate terminals of the fourth N-type MOSFET (N4) and the sixth P-type MOSFET (P6) of precharge circuit 14, respectively.

Set-reset flip-flop circuit 17 is set due to a transition to a low potential (i.e., Lo of second signal N_OUT) at first node N_OUT, and when fifth signal N_D1 outputted from inverter INV8 by the setting of set-reset flip-flop circuit 17 causes the fifth P-type MOSFET (P5) to turn ON and the third N-type MOSFET (N3) to turn OFF, first node N_OUT is connected to second voltage source VDD_HV. In contrast, set-reset flip-flop circuit 17 is reset due to a transition to a low potential (i.e., Lo of second signal OUT) at second node OUT, and when fifth signal D1 outputted from inverter INV9 by the resetting of set-reset flip-flop circuit 17 causes the sixth P-type MOSFET (P6) to turn ON and the fourth N-type MOSFET (N4) to turn OFF, second node OUT is connected to second voltage source VDD_HV.

Output circuit 18 includes: two two-or-more-stage inverter chains (here inverters INV4 and INV6 and inverters INV5 and INV7) for generating the pair of complementary fourth signals OUT1 and N_OUT1, based on the pair of third signals OUT0 and N_OUT0 outputted from set-reset flip-flop circuit 17 of precharge control circuit 16; and second phase alignment circuit 19 that adjusts the phases of the pair of complementary fourth signals OUT1 and N_OUT1 outputted from inverters INV6 and INV7 to be substantially aligned, by adjusting the phases of a pair of signals N_D2 and D2 outputted from inverters INV4 and INV5 to be substantially aligned.

Second phase alignment circuit 19 includes a third P-type MOSFET (P3) and a fourth P-type MOSFET (P4) that are cross-coupled. The source terminals of the third P-type MOSFET (P3) and the fourth P-type MOSFET (P4) are both connected to second voltage source VDD_HV. The gate terminal of the third P-type MOSFET (P3) is connected to the drain terminal of the fourth P-type MOSFET (P4), and the gate terminal of the fourth P-type MOSFET (P4) is connected to the drain terminal of the third P-type MOSFET (P3). The drain terminal of the third P-type MOSFET (P3) is connected to the input terminal of final-stage inverter INV6 included in one of the two two-or-more-stage inverter chains (here inverters INV4 and INV6 and inverters INV5 and INV7), and the drain terminal of the fourth P-type MOSFET (P4) is connected to the input terminal of final stage inverter INV7 included in the other of the two two-or-mor-stage inverter chains.

Next, the operations of first phase alignment circuit 13 of input circuit 12 in FIG. 1 are described as the characteristic operations of level shift circuit 10 according to the present embodiment.

When single-ended signal IN inputted to input circuit 12 transitions from a Lo (0 V) level to a Hi (VDD_LV) level, inverted signal N_IN0 that is delayed relative to inputted single-ended signal IN by a gate delay of inverter INV1 appears at the output of inverter INV1, and delayed signal IN0 that is delayed relative to inputted single-ended signal IN by a delay of transfer gate TG appears at the output of transfer gate TG. These delays are generally different from each other and vary depending on temperature, first voltage VDD_LV, manufacturing processes, etc.

When a delay that occurs when inverted signal N_IN0 transitions from the Hi (VDD_LV) level to the Lo (0 V) level is shorter than a delay that occurs when delayed signal IN0 transitions from the Lo (0 V) level to the Hi (VDD_LV) level, the first P-type MOSFET (P1) is ON since delayed signal IN0 is still at the Lo (0 V) level, and a delay that occurs when inverted signal N_IN0 transitions to the Lo (0 V) level is increased. Conversely, when the delay that occurs when inverted signal N_IN0 transitions from the Hi (VDD_LV) level to the Lo (0 V) level is longer than the delay that occurs when delayed signal IN0 transitions from the Lo (0 V) level to the Hi (VDD_LV) level, the second P-type MOSFET (P2) is OFF first since delayed signal IN0 is at the Hi (VDD_LV) level first, and the delay that occurs when delayed signal IN0 transitions to the Lo (0 V) level is reduced. As stated above, a delay from when the level of single-ended signal IN is transitioned until inverted signal N_IN0 appears and a delay until delayed signal IN0 appears are corrected to be substantially equal.

In contrast, in the case where inputted single-ended signal IN transitions from the Hi (VDD_LV) level to the Lo (0 V) level, when a delay that occurs when delayed signal IN0 transitions from the Hi (VDD_LV) level to the Lo (0 V) level is shorter than a delay that occurs when inverted signal N_IN0 transitions from the Lo (0 V) level to the Hi (VDD_LV) level, the second P-type MOSFET (P2) is ON since inverted signal N_IN0 is still at the Lo (0 V) level, and a delay that occurs when delayed signal IN0 transitions to the Lo (0 V) level is increased. Conversely, when the delay that occurs when delayed signal IN0 transitions from the Hi (VDD_LV) level to the Lo (0 V) level is longer than the delay that occurs when inverted signal N_IN0 transitions from the Lo (0 V) level to the Hi (VDD_LV) level, the first P-type MOSFET (P1) is OFF first since inverted signal N_IN0 is at the Hi (VDD_LV) level first, and the delay that occurs when inverted signal N_IN0 transitions to the Lo (0 V) level is reduced.

As stated above, when inputted single-ended signal IN transitions from the Lo (0 V) level to the Hi (VDD_LV) level and inputted single-ended signal IN transitions from the Hi (VDD_LV) level to the Lo (0 V) level, a delay from when the level of single-ended signal IN is transitioned until inverted signal N_IN0 appears and a delay until delayed signal IN0 appears are corrected to be substantially equal. A signal delayed by the same gate delay of inverters INV2 and INV3 appears. Accordingly, a delay from when inputted single-ended signal IN transitions from the Lo (0 V) level to the Hi (VDD_LV) level until first signal IN1 outputted from input circuit 12 transitions from the Lo (0 V) level to the Hi (VDD_LV) level becomes substantially equal to a delay from when inputted single-ended signal IN transitions from the Hi (VDD_LV) level to the Lo (0 V) level until first signal IN1 outputted from input circuit 12 transitions from the Hi (VDD_LV) level to the Lo (0 V) level.

Additionally, the operations of second phase alignment circuit 19 of output circuit 18 in FIG. 1 are described as the characteristic operations of level shift circuit 10 according to the present embodiment.

Second phase alignment circuit 19 operates under second voltage source VDD_HV that is the high-voltage source, and differs from first phase alignment circuit 13 in including a two-stage inverter chain (inverters INV4 and INV6) that receives third signal OUT0 from precharge control circuit 16 as an input and transmits fourth signal OUT1 as an output, and a two-stage inverter chain (inverters INV5 and INV7) that receives third signal N_OUT0 from precharge control circuit 16 as an input and transmits fourth signal N_OUT1 as an output. Consequently, a delay until single-ended signal IN appears in fourth signal OUT1 and a delay until an inverted signal of single-ended signal IN appears in fourth signal N_OUT1 are corrected to be substantially equal.

As stated above, a delay from when inputted single-ended signal IN transitions from the Lo (0 V) level to the Hi (VDD_LV) level until fourth signal OUT1 from output circuit 18 transitions from the Lo (0 V) level to the Hi (VDD_LV) level becomes substantially equal to a delay from when inputted single-ended signal IN transitions from the Hi (VDD_LV) level to the Lo (0 V) level until fourth signal OUT1 from output circuit 18 transitions from the Hi (VDD_LV) level to the Lo (0 V) level. Accordingly, when inputted single-ended signal IN repeatedly has a fixed Hi (VDD_LV) level period and a fixed Lo (0 V) period, relative to a fixed duty cycle, that is, the ratio of the Hi (VDD_LV) level period to the sum of the Hi (VDD_LV) level period and the Lo (0 V) level period, the duty cycle of an output signal repeatedly outputted from output circuit 18 of level shift circuit 10, that is, the ratio of the Hi (VDD_LV) level period to the sum of the Hi (VDD_LV) level period and the Lo (0 V) level period, becomes a value substantially equal to the duty cycle of an input signal, and it is possible to suppress variations in the duty cycle of the output signal due to variations in temperature, power supply voltage, manufacturing processes, etc.

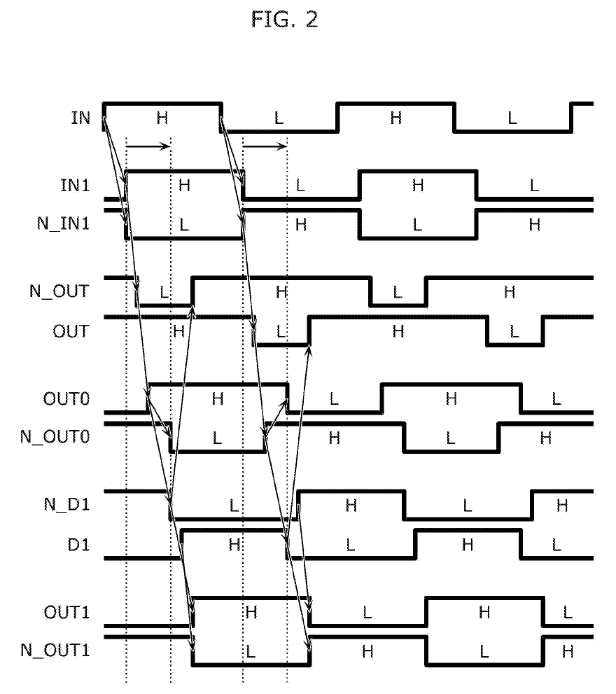

FIG. 2 is a timing chart showing an operation example of level shift circuit 10 according to the embodiment. The figure shows timing examples of single-ended signal IN inputted to input terminal IN of input circuit 12, a pair of complementary first signals IN1 and N_IN1 outputted from input circuit 12, a pair of second signals N_OUT and OUT outputted from precharge circuit 14, a pair of third signals OUT0 and N_OUT0 outputted from precharge control circuit 16, a pair of fifth signals N_D1 and D1 outputted from precharge control circuit 16, and a pair of complementary fourth signals OUT1 and N_OUT1 outputted from output circuit 18.

In input circuit 12, single-ended signal IN (i.e., an input signal generated using first voltage source VDD_LV as a power source) inputted from input terminal IN is converted into complementary signals by the two-or-more-stage inverter chain (here inverters INV1 and INV2), one-stage transfer gate TG, and the one-or-more-stage inverter chain (here inverter INV3), and into the pair of complementary first signals IN1 and N_IN1 whose phases are adjusted to be substantially aligned by phase alignment being applied to by first phase alignment circuit 13.

The pair of complementary first signals IN1 and N_IN1 is converted into the pair of second signals N_OUT and OUT whose Low period starts at a rising edge by precharge circuit 14, the pair of second signals N_OUT and OUT being generated using second voltage source VDD_HV as a power source.

The pair of second signals N_OUT and OUT is converted into the pair of third signals OUT0 and N_OUT0 whose Hi period starts at a falling edge by set-reset flip-flop circuit 17 of precharge control circuit 16.

Moreover, the pair of third signals OUT0 and N_OUT0 is converted into the pair of fifth signals N_D1 and D1 by logical inversion and a delay being applied to by two inverters INV8 and INV9 of precharge control circuit 16. The pair of fifth signals N_D1 and D1 is supplied to the gate terminals of the fifth P-type MOSFET (P5) and the third N-type MOSFET (N3) of precharge circuit 14 and the gate terminals of the sixth P-type MOSFET (P6) and the fourth N-type MOSFET (N4) of precharge circuit 14. Accordingly, the pair of second signals N_OUT and OUT outputted from precharge circuit 14 is returned to the Hi level.

Furthermore, in output circuit 18, the pair of third signals OUT0 and N_OUT0 is converted into output signals N_D2 and D2 by logical inversion and a delay being applied to by inverters INV4 and INV5. Output signals N_D2 and D2 are outputted as the pair of complementary fourth signals OUT1 and N_OUT1 by phase alignment being applied to by second phase alignment circuit 19 and further by logical inversion and a delay being applied to by inverters INV6 and INV7.

Since level shift circuit 10 according to the embodiment receives a single-ended signal as an input, first phase alignment circuit 13 is provided in input circuit 12, and second phase alignment circuit 19 is also provided in output circuit 18 as above, a level shift circuit that makes it possible to receive a single-ended signal as an input and suppress variations in the duty cycle of an output signal relative to the duty cycle of an input signal is achieved.

Moreover, in the present embodiment, the gate terminal of the first N-type MOSFET (N1) is connected to the output terminal of final-stage inverter INV2 included in the two-or-more-stage inverter chain (here inverters INV1 and INV2), and the gate terminal of the second N-type MOSFET (N2) is connected to the output terminal of final-stage inverter INV3 included in one-stage transfer gate TG and the one-or-more-stage inverter chain (here inverter INV3). The drain terminal of the first N-type MOSFET (N1) is connected to first node N_OUT, and the drain terminal of the second N-type MOSFET (N2) is connected to second node OUT. Precharge circuit 14 further includes the third N-type MOSFET (N3), the fourth N-type MOSFET (N4), the fifth P-type MOSFET (P5), and the sixth P-type MOSFET (P6). The source terminals of the third N-type MOSFET (N3) and the fourth N-type MOSFET (N4) are both grounded. The drain terminal of the third N-type MOSFET (N3) is connected to the source terminal of the first N-type MOSFET (N1), and the drain terminal of the fourth N-type MOSFET (N4) is connected to the source terminal of the second N-type MOSFET (N2). The source terminals of the fifth P-type MOSFET (P5) and the sixth P-type MOSFET (P6) are both connected to second voltage source VDD_HV. The drain terminal of the fifth P-type MOSFET (P5) is connected to the drain terminal of the first N-type MOSFET (N1), and the drain terminal of the sixth P-type MOSFET (P6) is connected to the drain terminal of the second N-type MOSFET (N2). Precharge control circuit 16 includes set-reset flip-flop circuit 17. First node N_OUT and second node OUT are connected to respective input terminals of set-reset flip-flop circuit 17. Two output terminals of precharge control circuit 16 are connected to the gate terminals of the third N-type MOSFET (N3) and the fifth P-type MOSFET (P5) of precharge circuit 14 and the gate terminals of the fourth N-type MOSFET (N4) and the sixth P-type MOSFET (P6), respectively. Set-reset flip-flop circuit 17 is set due to a transition to a low potential at first node N_OUT, and first node N_OUT is connected to second voltage source VDD_HV by the setting of set-reset flip-flop circuit 17. Set-reset flip-flop circuit 17 is reset due to a transition to a low potential at second node N_OUT, and second node OUT is connected to second voltage source VDD_HV by the resetting of set-reset flip-flop circuit 17.

Accordingly, since precharge circuit 14 includes, in addition to the first N-type MOSFET (N1) and the second N-type MOSFET (N2), the fifth P-type MOSFET (P5) and the third N-type MOSFET (N3) that are connected in series with the first N-type MOSFET (N1) and have complementary logic, and the sixth P-type MOSFET (P6) and the fourth N-type MOSFET (N4) that are connected in series with the second N-type MOSFET (N2) and have complementary logic, a shoot-through current that flows through the first N-type MOSFET (N1) and the second N-type MOSFET (N2) is reduced.

Furthermore, precharge circuit 14 further includes the seventh P-type MOSFET (P7). The drain terminal and the source terminal of the seventh P-type MOSFET (P7) are connected to first node N_OUT and second node OUT, respectively. The gate terminal of the seventh P-type MOSFET (P7) is grounded. This causes first node N_OUT and second node OUT to avoid entering a high impedance state, and first node N_OUT and second node OUT are connected to second voltage source VDD_HV instead of the high impedance state.

A level shift method according to the present embodiment is a level shift method that shifts a logic level, the level shift method including: converting, by input circuit 12, an input signal into a pair of complementary first signals IN1 and N_IN1, the input signal being generated using first voltage source VDD_LV as a power source; outputting, by precharge circuit 14, a pair of second signals N_OUT and OUT corresponding to the pair of complementary first signals IN1 and N_IN1 from first node N_OUT and second node OUT after precharging first node N_OUT and second node OUT to an electric potential of second voltage source VDD_HV, first node N_OUT and second node OUT being included in precharge circuit 14; outputting a pair of third signals OUT0 and N_OUT and controlling precharge circuit 14 by precharge control circuit 16, based on the pair of second signals N_OUT and OUT outputted in the outputting of the pair of second signals N_OUT and OUT; and adjusting, by input circuit 12 and output circuit 18, phases of the pair of complementary first signals IN1 and N_IN1 and the pair of third signals OUT0 and N_OUT0 to be substantially aligned.

Accordingly, since the level shift method according to the embodiment includes receiving a single-ended signal as an input and adjusting, by input circuit 12 and output circuit 18, the phases of the pair of complementary first signals IN1 and N_IN1 and the pair of third signals OUT0 and N_OUT0 to be substantially aligned, a level shift method that makes it possible to receive a single-ended signal as an input and suppress variations in the duty cycle of an output signal relative the duty cycle of an input signal is achieved.

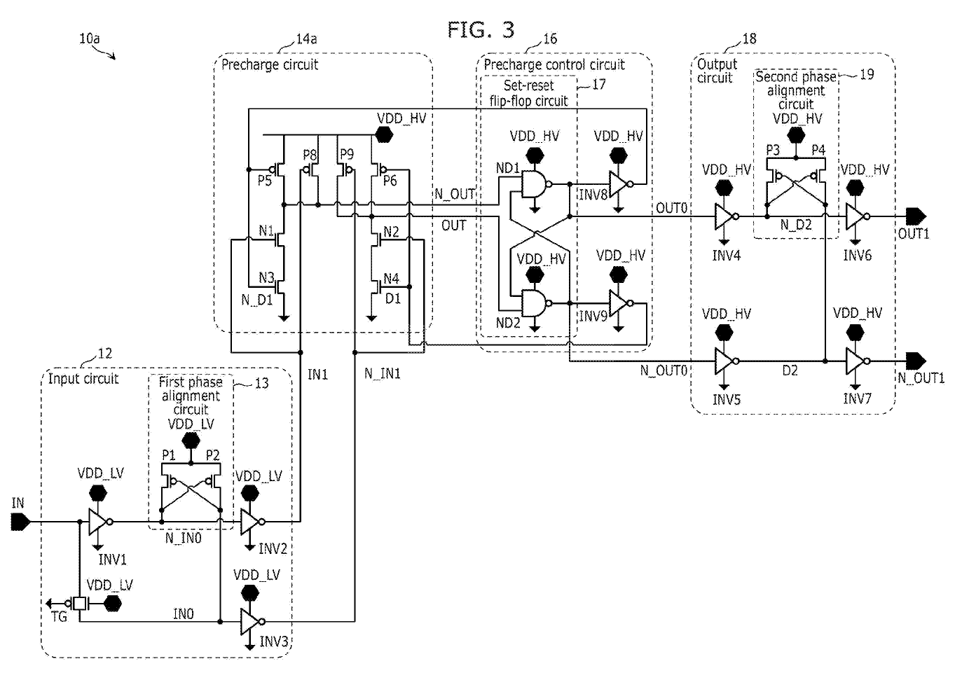

FIG. 3 is a circuit diagram showing level shift circuit 10a according to Variation 1 of the embodiment. Level shift circuit 10a according to the present variation includes an eighth P-type MOSFET (P8) and a ninth P-type MOSFET (P9) instead of the seventh P-type MOSFET (P7) included in level shift circuit 10 according to the above embodiment. In other words, precharge circuit 14a of level shift circuit 10a according to the present variation includes the eighth P-type MOSFET (P8) and the ninth P-type MOSFET (P9) instead of the seventh P-type MOSFET (P7) included in precharge circuit 14 of level shift circuit 10 according to the above embodiment.

The source terminals of the eighth P-type MOSFET (P8) and the ninth P-type MOSFET (P9) are both connected to second voltage source VDD_HV. The drain terminal of the eighth P-type MOSFET (P8) is connected to first node N_OUT, and the gate terminal of the eighth P-type MOSFET (P8) is connected to the gate terminal of the second N-type MOSFET (N2). The drain terminal of the ninth P-type MOSFET (P9) is connected to second node OUT, and the gate terminal of the ninth P-type MOSFET (P9) is connected to the gate terminal of the first N-type MOSFET (N1).

In precharge circuit 14 according to the above embodiment, since the gate terminal of the seventh P-type MOSFET (P7) is grounded, a period during which, immediately after the first N-type MOSFET (N1) turns ON when first signal IN1 becomes Hi, the third N-type MOSFET (N3) turns ON because fifth signal N_D1 is Hi and the sixth P-type MOSFET (P6) turns ON because fifth signal D1 is Lo arises. In the period, a shoot-through current flows from second voltage source VDD_HV to ground via the sixth P-type MOSFET (P6), the seventh P-type MOSFET (P7), the first N-type MOSFET (N1), and the third N-type MOSFET (N3), and at the same time an operation is delayed by the period and an operating speed is reduced.

Likewise, a period during which, immediately after the second N-type MOSFET (N2) turns ON when first signal N_IN1 becomes Hi, the fourth N-type MOSFET (N4) turns ON because fifth signal D1 is Hi and the fifth P-type MOSFET (P5) turns ON because fifth signal N_D1 is Lo also arises. In the period, a shoot-through current flows from second voltage source VDD_HV to ground via the fifth P-type MOSFET (P5), the seventh P-type MOSFET (P7), the second N-type MOSFET (N2), and the fourth N-type MOSFET (N4), and at the same time an operation is delayed by the period and an operating speed is reduced.

In contrast, in precharge circuit 14a according to the present variation, since the eighth P-type MOSFET (P8) and the ninth P-type MOSFET (P9) having the above-described connection relationship are provided, even immediately after the first N-type MOSFET (N1) turns ON when first signal IN1 becomes Hi, the eighth P-type MOSFET (P8) including the gate terminal connected to first signal IN1 simultaneously turns OFF. For this reason, a shoot-through current that flows from second voltage source VDD_HV to ground via the eighth P-type MOSFET (P8) is interrupted, and a reduction in operating speed is also suppressed.

Similarly, even immediately after the second N-type MOSFET (N2) turns ON when first signal N_IN1 becomes Hi, the ninth P-type MOSFET (P9) including the gate terminal connected to first signal N_IN1 simultaneously turns OFF. For this reason, a shoot-through current that flows from second voltage source VDD_HV to ground via the first N-type MOSFET (N1) or the second N-type MOSFET (N2) is interrupted, and a reduction in operating speed is also suppressed. Accordingly, level shift circuit 10a according to the present variation reduces current consumption and accelerates an operation, compared to level shift circuit 10 according to the embodiment.

As stated above, in level shift circuit 10a according to the present variation, precharge circuit 14a includes the eighth P-type MOSFET (P8) and the ninth P-type MOSFET (P9), the source terminals of the eighth P-type MOSFET (P8) and the ninth P-type MOSFET (P9) are both connected to second voltage source VDD_HV, the drain terminal of the eighth P-type MOSFET (P8) is connected to first node N_OUT, the gate terminal of the eighth P-type MOSFET (P8) is connected to the gate terminal of the second N-type MOSFET (N2), the drain terminal of the ninth P-type MOSFET (P9) is connected to second node OUT, and the gate terminal of the ninth P-type MOSFET (P9) is connected to the gate terminal of the first N-type MOSFET (N1). Accordingly, current consumption is reduced by decreasing a shoot-through current that flows through the first N-type MOSFET (N1) and the second N-type MOSFET (N2), and an operation is accelerated.

It should be noted that a source-drain current when the eighth P-type MOSFET (P8) and the ninth P-type MOSFET (P9) are ON may be (i) less than 0.1 times a source-drain current when the first N-type MOSFET (N1) and the second N-type MOSFET (N2) are ON, and (ii) more than 10 times a source-drain current when the first N-type MOSFET (N1) and the second N-type MOSFET (N2) are OFF. Accordingly, level shift circuit 10a that makes it possible to decrease the above shoot-through current stably relative to variations in semiconductor manufacturing processes for achieving level shift circuit 10a is achieved.

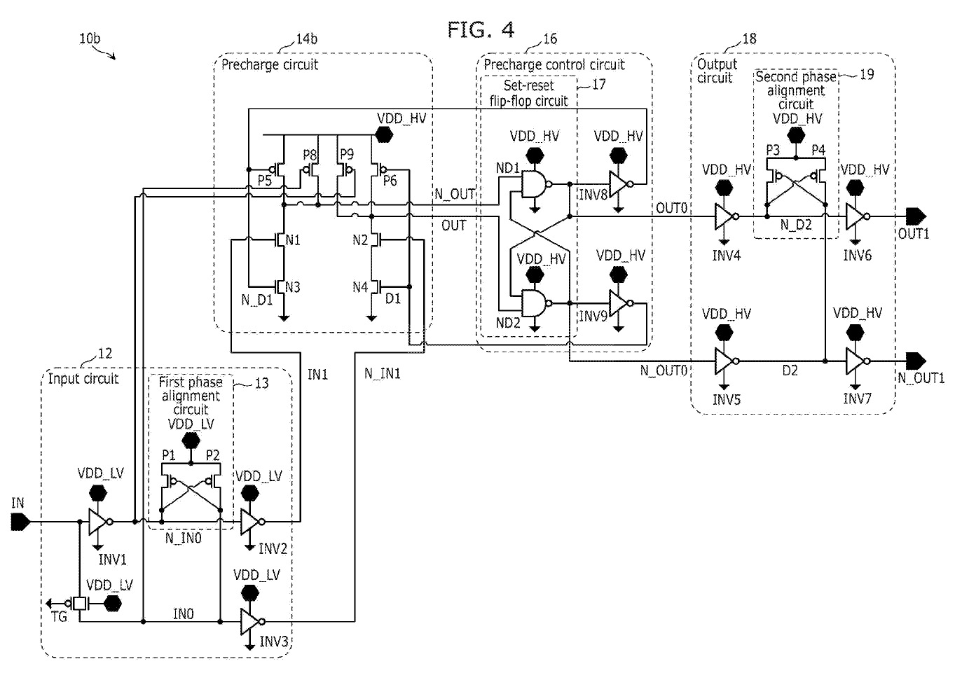

FIG. 4 is a circuit diagram showing level shift circuit 10b according to Variation 2 of the embodiment. Level shift circuit 10b according to the present variation differs from level shift circuit 10a according to Variation 1 above only in connection destinations of the gate terminals of the eighth P-type MOSFET (P8) and the ninth P-type MOSFET (P9) in precharge circuit 14b. In other words, in level shift circuit 10b according to the present variation, the gate terminal of the eighth P-type MOSFET (P8) is connected to the input terminal of inverter INV3 including the output terminal connected to the gate terminal of the second N-type MOSFET (N2), among the two-or-more-stage inverter chain (here inverters INV1 and INV2), one-stage transfer gate TG, and the one-or-more-stage inverter chain (here inverter INV3) included in input circuit 12. On the other hand, the gate terminal of the ninth P-type MOSFET (P9) is connected to the input terminal of inverter INV2 including the output terminal connected to the gate terminal of the first N-type MOSFET (N1), among the two-or-more-stage inverter chain (here inverters INV1 and INV2), one-stage transfer gate TG, and the one-or-more-stage inverter chain (here inverter INV3) included in input circuit 12.

Because of such a connection relationship, in level shift circuit 10b according to the present variation, a control signal inputted to the gate terminals of the eighth P-type MOSFET (P8) and the ninth P-type MOSFET (P9) is a signal advanced by a delay caused by one-stage inverters INV2 and INV3, compared to level shift circuit 10a according to Variation 1 above.

In consequence, a shoot-through current that flows through the eighth P-type MOSFET (P8) and the ninth P-type MOSFET (P9) is interrupted more quickly in level shift circuit 10b according to the present variation than in level shift circuit 10a according to Variation 1, and transitions to a low potential at first node N_OUT and second node OUT are accelerated. For this reason, level shift circuit 10b according to the present variation operates at high speed due to the decrease of the shoot-through current and the reduction in delay time, compared to level shift circuit 10a according to Variation 1.

It should be noted that a source-drain current when the eighth P-type MOSFET (P8) and the ninth P-type MOSFET (P9) are ON may be (i) less than 0.1 times a source-drain current when the first N-type MOSFET (N1) and the second N-type MOSFET (N2) are ON, and (ii) more than 10 times a source-drain current when the first N-type MOSFET (N1) and the second N-type MOSFET (N2) are OFF. Accordingly, level shift circuit 10b that makes it possible to decrease the above shoot-through current stably relative to variations in semiconductor manufacturing processes for achieving level shift circuit 10b is achieved.

Although the level shift circuit and the level shift method according to the present disclosure are described above based on the embodiment and the variations, the present disclosure is not limited to these embodiment and variations. Hereinafter, level shift circuits according to Technique 1 to Technique 6 of the embodiment that are achieved by carrying out various modifications to the above embodiment and variations or removing circuit elements from the above embodiment and variations are described.

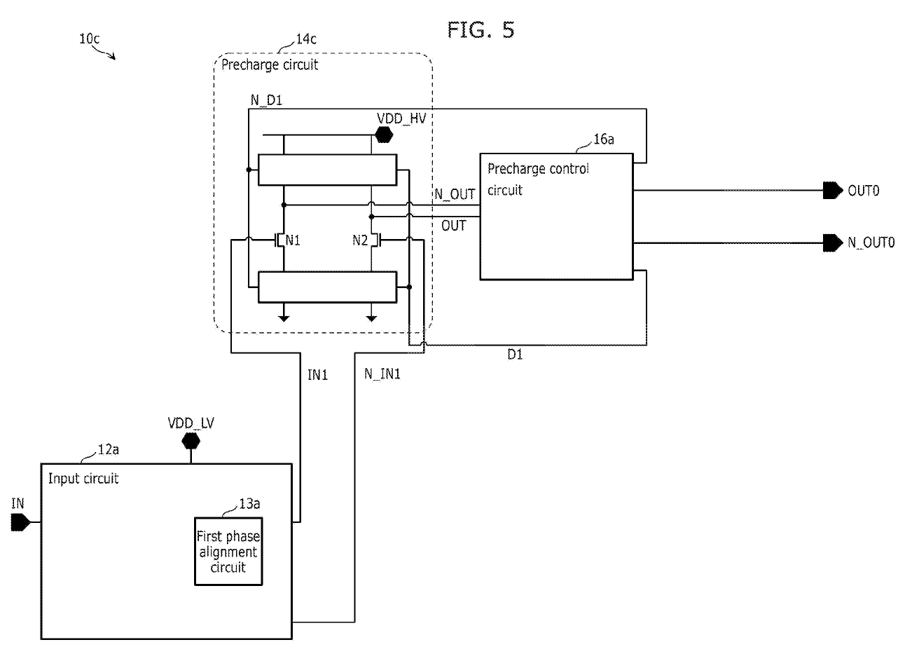

FIG. 5 is a block diagram showing a configuration of level shift circuit 10c according to Technique 1 of the embodiment. It should be noted that the figure emphasizes types and functions of blocks, and omits specific circuit configurations such as transistors depending on the block.

Level shift circuit 10c according to Technique 1 is a level shift circuit that shifts a logic level, and includes: input circuit 12a that converts an input signal into a pair of complementary first signals IN1 and N_IN1, the input signal being generated using first voltage source VDD_LV as a power source; precharge circuit 14c that includes first node N_OUT, second node OUT, a first N-type MOSFET (N1) that is an example of a first transistor, and a second N-type MOSFET (N2) that is an example of a second transistor, and outputs a pair of second signals N_OUT and OUT corresponding to the pair of complementary first signals IN1 and N_IN1 from first node N_OUT and second node OUT after precharging first node N_OUT and second node OUT to an electric potential of second voltage source VDD_HV, the pair of complementary first signals N_OUT and OUT outputted from input circuit 12a being inputted to the first N-type MOSFET (N1) and the second N-type MOSFET (N2); and precharge control circuit 16a that outputs a pair of third signals OUT0 and N_OUT0 and controls precharge circuit 14c, based on the pair of second signals N_OUT and OUT outputted from precharge circuit 14c. Input circuit 12a includes first phase alignment circuit 13a that adjusts the phases of the pair of complementary first signals IN1 and N_IN1 to be substantially aligned.

As with input circuit 12 according to the embodiment, input circuit 12a includes first phase alignment circuit 13a that converts single-ended signal IN into the pair of complementary first signals IN1 and N_IN1 and adjusts the phases of the pair of complementary first signals IN1 and N_IN1 to be substantially aligned. However, first phase alignment circuit 13a may include a circuit (e.g., a latch circuit including two inverters that are cross-coupled) different from the circuit included in first phase alignment circuit 13 according to the embodiment.

As with precharge circuit 14 according to the embodiment, although precharge circuit 14c includes the first N-type MOSFET (N1) and the second N-type MOSFET (N2), precharge circuit 14c may include other circuits (e.g., circuits each having a different number of transistors connected in series or different points connected to transistors) instead of the third N-type MOSFET (N3), the fourth N-type MOSFET (N4), the fifth P-type MOSFET (P5), and the sixth P-type MOSFET (P6).

Precharge control circuit 16a may be a circuit that outputs the pair of third signals OUT0 and N_OUT0 and controls precharge circuit 14c, based on the pair of second signals N_OUT and OUT outputted from precharge circuit 14c. Precharge control circuit 16a may include other circuits (e.g., flip-flop circuits of different types) instead of set-reset flip-flop circuit 17 and two inverters INV8 and INV9 according to the embodiment.

It should be noted that level shift circuit 10c according to Technique 1 does not include output circuit 18 according to the above embodiment. Since even such level shift circuit 10c receives a single-ended signal as an input and first phase alignment circuit 13a is provided in input circuit 12a, a level shift circuit that makes it possible to receive a single-ended signal as an input and suppress variations in the duty cycle of an output signal relative to the duty cycle of an input signal is achieved.

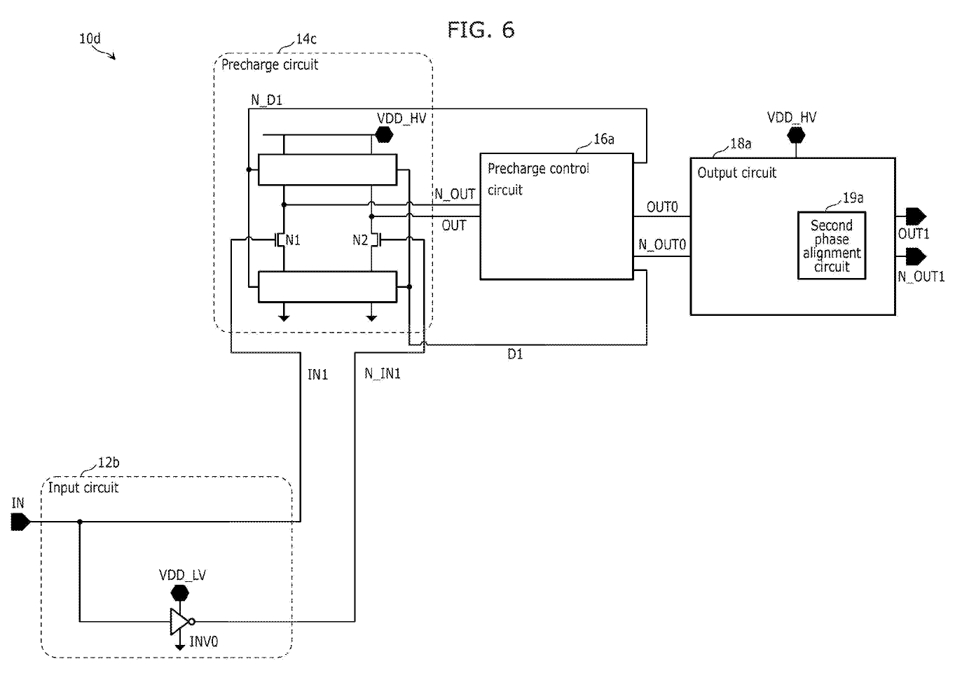

FIG. 6 is a block diagram showing a configuration of level shift circuit 10d according to Technique 2 of the embodiment. It should be noted that the figure emphasizes types and functions of blocks, and omits specific circuit configurations such as transistors depending on the block.

Level shift circuit 10d according to Technique 2 is a level shift circuit that shifts a logic level, and includes: input circuit 12b that converts an input signal into a pair of complementary first signals IN1 and N_IN1, the input signal being generated using first voltage source VDD_LV as a power source; precharge circuit 14c that includes first node N_OUT, second node OUT, a first N-type MOSFET (N1) that is an example of a first transistor, and a second N-type MOSFET (N2) that is an example of a second transistor, and outputs a pair of second signals N_OUT and OUT corresponding to the pair of complementary first signals IN1 and N_IN1 from first node N_OUT and second node OUT after precharging first node N_OUT and second node OUT to an electric potential of second voltage source VDD_HV, the pair of complementary first signals N_OUT and OUT outputted from input circuit 12b being inputted to the first N-type MOSFET (N1) and the second N-type MOSFET (N2); precharge control circuit 16a that outputs a pair of third signals OUT0 and N_OUT0 and controls precharge circuit 14c, based on the pair of second signals N_OUT and OUT outputted from precharge circuit 14c; and output circuit 18a that outputs a pair of complementary fourth signals OUT1 and N_OUT1, based on the pair of third signals OUT0 and N_OUT0 outputted from precharge control circuit 16a. Output circuit 18a includes second phase alignment circuit 19a that adjusts the phases of the pair of complementary fourth signals OUT1 and N_OUT1 to be substantially aligned.

Input circuit 12b is a circuit that receives a single-ended signal as an input and converts the single-ended signal into the pair of complementary first signals IN1 and N_IN1, and includes, for example, a branch wire and inverter INV0 provided to one end of the branch wire as shown in the figure.

Output circuit 18a is a circuit that outputs the pair of complementary fourth signals OUT1 and N_OUT1, and includes second phase alignment circuit 19a that adjusts the phases of the pair of complementary fourth signals OUT1 and N_OUT1 to be substantially aligned. However, second phase alignment circuit 19a may include a circuit (e.g., a latch circuit including two inverters that are cross-coupled) different from the circuit included in second phase alignment circuit 19 according to the embodiment.

Since level shift circuit 10d according to such Technique 2 includes input circuit 12b that receives a single-ended signal as an input, and output circuit 18a that includes second phase alignment circuit 19a, a level shift circuit that makes it possible to receive a single-ended signal as an input and suppress variations in the duty cycle of an output signal relative to the duty cycle of an input signal is achieved.

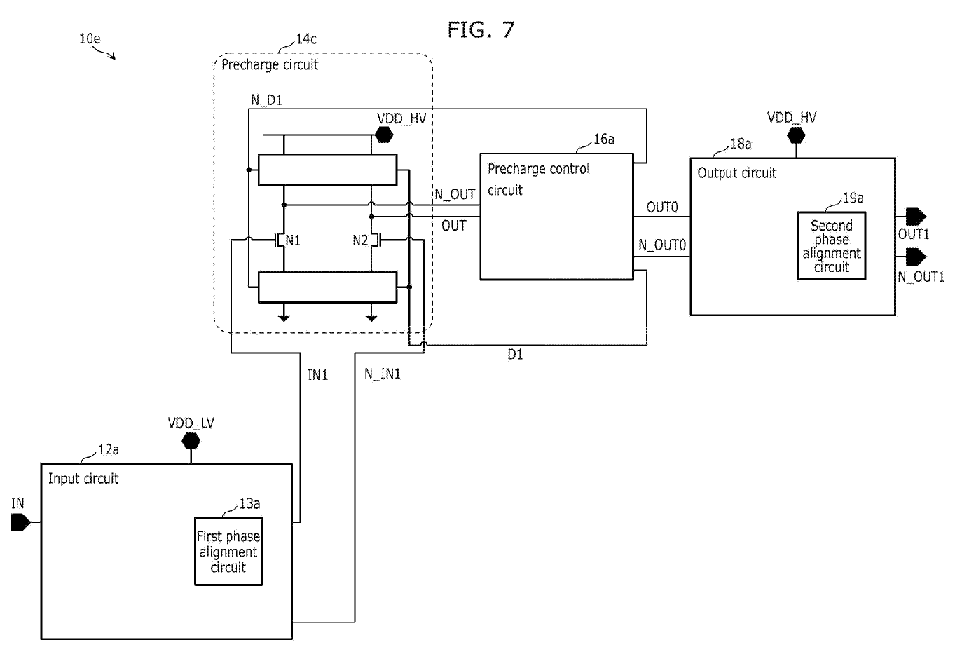

FIG. 7 is a block diagram showing a configuration of level shift circuit 10e according to Technique 3 of the embodiment. It should be noted that the figure emphasizes types and functions of blocks, and omits specific circuit configurations such as transistors depending on the block.

Level shift circuit 10e according to Technique 3 is configured by further adding, to level shift circuit 10c according to Technique 1 above, output circuit 18a that outputs a pair of complementary fourth signals OUT1 and N_OUT1, based on the pair of third signals OUT0 and N_OUT0 outputted from precharge control circuit 16a. Output circuit 18a includes second phase alignment circuit 19a that adjusts the phases of the pair of complementary fourth signals OUT1 and N_OUT1 to be substantially aligned.

Since level shift circuit 10e according to such Technique 3 includes input circuit 12a that receives a single-ended signal as an input and includes first phase alignment circuit 13a, and output circuit 18a that includes second phase alignment circuit 19a, a level shift circuit that makes it possible to receive a single-ended signal as an input and suppress variations in the duty cycle of an output signal relative to the duty cycle of an input signal is achieved.

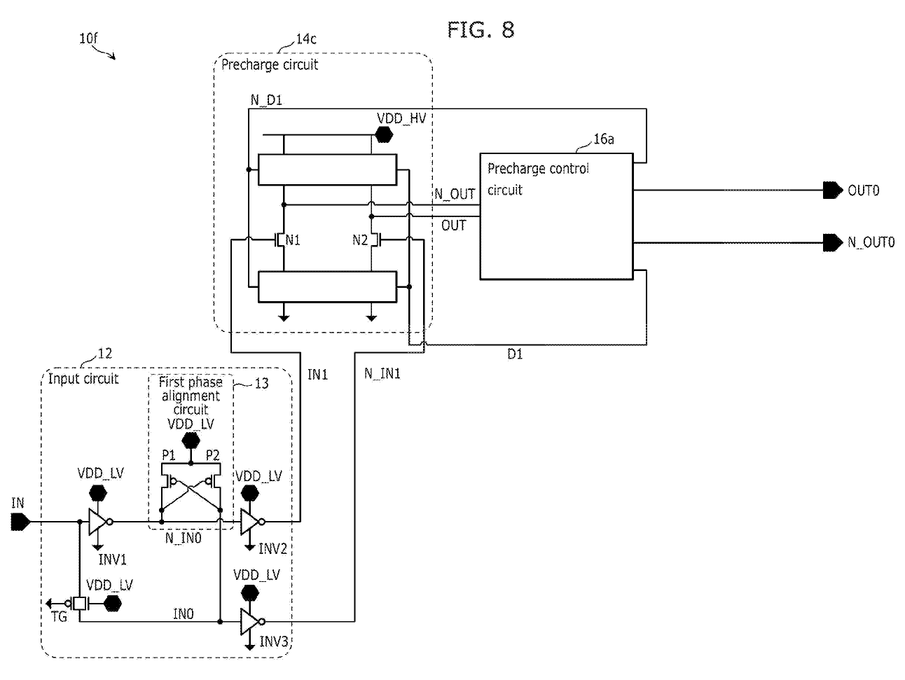

FIG. 8 is a block diagram showing a configuration of level shift circuit 10f according to Technique 4 of the embodiment. It should be noted that the figure emphasizes types and functions of blocks, and omits specific circuit configurations such as transistors depending on the block.

Level shift circuit 10f according to Technique 4 is equivalent to a circuit obtained by replacing input circuit 12a of level shift circuit 10c according to Technique 1 above with input circuit 12 according to the embodiment.

As with level shift circuit 10c according to Technique 1 above, since level shift circuit 10f according to such Technique 4 receives a single-ended signal as an input and first phase alignment circuit 13 is provided in input circuit 12, a level shift circuit that makes it possible to receive a single-ended signal as an input and suppress variations in the duty cycle of an output signal relative to the duty cycle of an input signal is achieved.

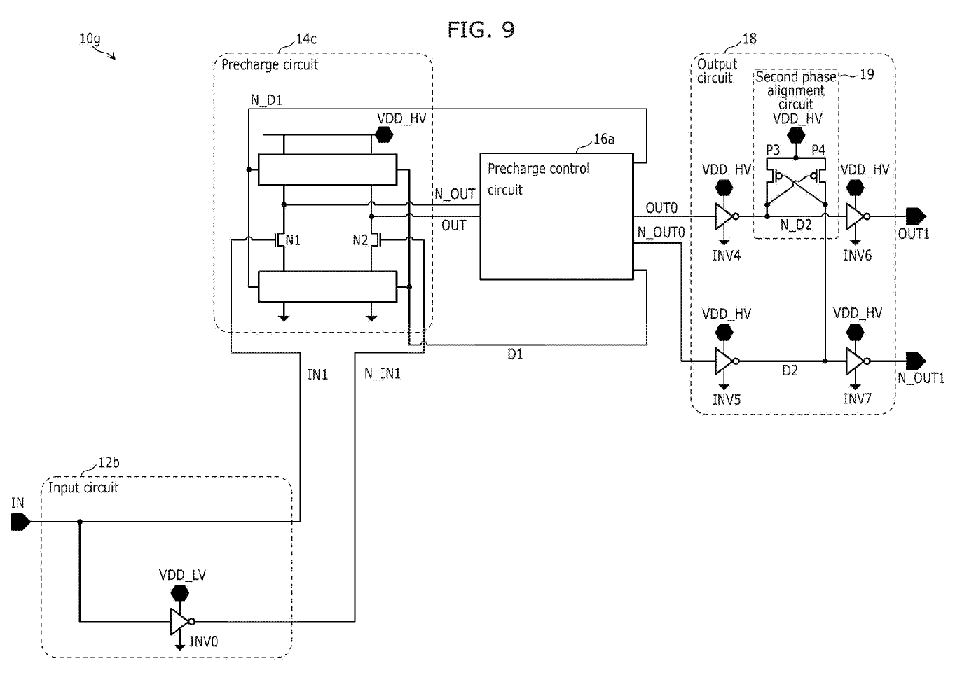

FIG. 9 is a block diagram showing a configuration of level shift circuit 10g according to Technique 5 of the embodiment. It should be noted that the figure emphasizes types and functions of blocks, and omits specific circuit configurations such as transistors depending on the block.

Level shift circuit 10g according to Technique 5 is equivalent to a circuit obtained by replacing output circuit 18a of level shift circuit 10d according to Technique 2 above with output circuit 18 according to the embodiment.

As with level shift circuit 10d according to Technique 2 above, since level shift circuit 10g according to such Technique 5 includes input circuit 12b that receives a single-ended signal as an input, and output circuit 18 that includes second phase alignment circuit 19, a level shift circuit that makes it possible to receive a single-ended signal as an input and suppress variations in the duty cycle of an output signal relative to the duty cycle of an input signal is achieved.

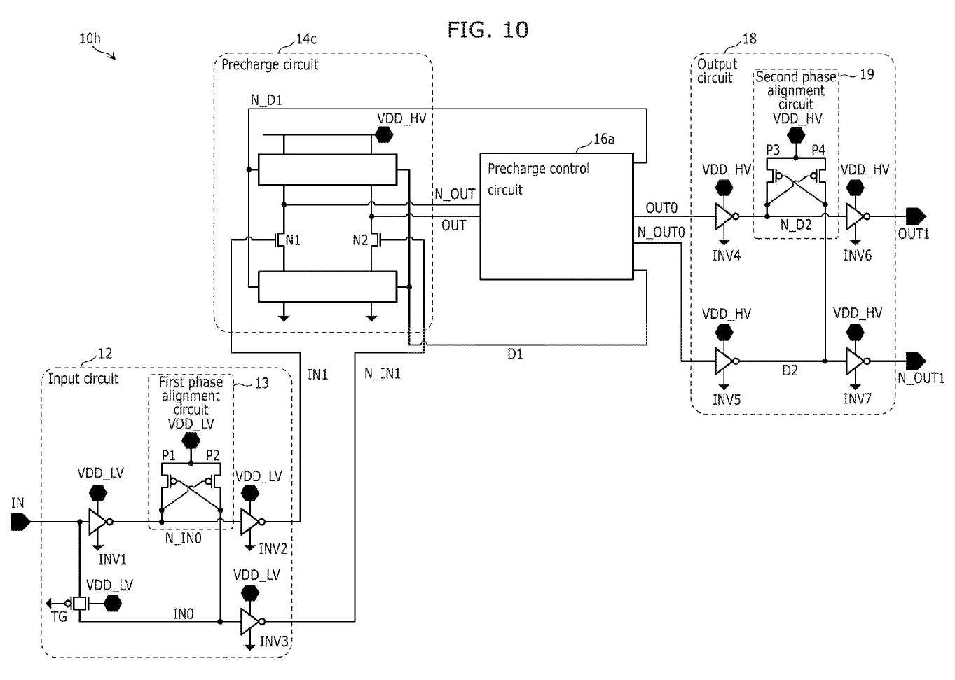

FIG. 10 is a block diagram showing a configuration of level shift circuit 10h according to Technique 6 of the embodiment. It should be noted that the figure emphasizes types and functions of blocks, and omits specific circuit configurations such as transistors depending on the block. Level shift circuit 10h according to Technique 6 is equivalent to a circuit obtained by further adding output circuit 18 according to the embodiment to level shift circuit 10f according to Technique 4 above.

As with level shift circuit 10f according to Technique 4 above, since level shift circuit 10h according to such Technique 6 receives a single-ended signal as an input, and includes input circuit 12 that includes first phase alignment circuit 13, and output circuit 18 that includes second phase alignment circuit 19, a level shift circuit that makes it possible to receive a single-ended signal as an input and suppress variations in the duty cycle of an output signal relative to the duty cycle of an input signal is achieved.

Although the level shift circuit and the level shift method according to the present disclosure are described above based on the embodiment, the variations, and Techniques 1 to 6, the present disclosure is not limited to the embodiment, the variations, and Techniques 1 to 6. Forms obtained by various modifications to the embodiment, the variations, and Techniques 1 to 6 that can be conceived by a person skilled in the art, and other forms resulting from combinations of some of the constituent elements in the embodiment, the variations, and Techniques 1 to 6 are included within the scope of the present disclosure, as long as they do not depart from the essence of the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is applicable as a level shift circuit that shifts a logic level, especially as a level shift circuit that makes it possible to receive a single-ended signal as an input and suppress variations in the duty cycle of an output signal relative to the duty cycle of an input signal due to changes in temperature, power supply voltage, manufacturing processes, etc.

1. A level shift circuit that shifts a logic level, the level shift circuit comprising:
an input circuit that converts an input signal into a pair of complementary first signals, the input signal being generated using a first voltage source as a power source;
a precharge circuit that includes a first node, a second node, a first transistor, and a second transistor, and outputs a pair of second signals corresponding to the pair of complementary first signals from the first node and the second node after precharging the first node and the second node to an electric potential of a second voltage source, the pair of complementary first signals outputted from the input circuit being inputted to the first transistor and the second transistor; and
a precharge control circuit that outputs a pair of third signals and controls the precharge circuit, based on the pair of second signals outputted from the precharge circuit,
wherein the input circuit includes a first phase alignment circuit that adjusts phases of the pair of complementary first signals to be substantially aligned.

2. A level shift circuit that shifts a logic level, the level shift circuit comprising:
an input circuit that converts an input signal into a pair of complementary first signals, the input signal being generated using a first voltage source as a power source;
a precharge circuit that includes a first node, a second node, a first transistor, and a second transistor, and outputs a pair of second signals corresponding to the pair of complementary first signals from the first node and the second node after precharging the first node and the second node to an electric potential of a second voltage source, the pair of complementary first signals outputted from the input circuit being inputted to the first transistor and the second transistor;
a precharge control circuit that outputs a pair of third signals and controls the precharge circuit, based on the pair of second signals outputted from the precharge circuit; and
an output circuit that outputs a pair of complementary fourth signals, based on the pair of third signals outputted from the precharge control circuit,
wherein the output circuit includes a second phase alignment circuit that adjusts phases of the pair of complementary fourth signals to be substantially aligned.

3. The level shift circuit according to claim 1, further comprising:
an output circuit that outputs a pair of complementary fourth signals, based on the pair of third signals outputted from the precharge control circuit,
wherein the output circuit includes a second phase alignment circuit that adjusts phases of the pair of complementary fourth signals to be substantially aligned.

4. The level shift circuit according to claim 1,
wherein the input circuit includes: a two-or-more-stage inverter chain for generating the pair of complementary first signals; a one-stage transfer gate; and a one-or-more-stage inverter chain,
the first phase alignment circuit includes a first P-type metal-oxide-semiconductor field-effect transistor (MOSFET) and a second P-type MOSFET,
a source terminal of the first P-type MOSFET and a source terminal of the second P-type MOSFET are connected to the first voltage source,
a gate terminal of the first P-type MOSFET is connected to a drain terminal of the second P-type MOSFET, and a gate terminal of the second P-type MOSFET is connected to a drain terminal of the first P-type MOSFET, and
the drain terminal of the first P-type MOSFET is connected to an input terminal of a final-stage inverter included in the two-or-more-stage inverter chain, and the drain terminal of the second P-type MOSFET is connected to an input terminal of a final-stage inverter included in the one-stage transfer gate and the one-or-more-stage inverter chain.

5. The level shift circuit according to claim 2,
wherein the output circuit includes two two-or-more-stage inverter chains for generating the pair of complementary fourth signals,
the second phase alignment circuit includes a third P-type metal-oxide-semiconductor field-effect transistor (MOSFET) and a fourth P-type MOSFET,
a source terminal of the third P-type MOSFET and a source terminal of the fourth P-type MOSFET are connected to the second voltage source,
a gate terminal of the third P-type MOSFET is connected to a drain terminal of the fourth P-type MOSFET, and a gate terminal of the fourth P-type MOSFET is connected to a drain terminal of the third P-type MOSFET, and
the drain terminal of the third P-type MOSFET is connected to an input terminal of a final-stage inverter included in one of the two two-or-more-stage inverter chains, and the drain terminal of the fourth P-type MOSFET is connected to an input terminal of a final-stage inverter included in an other of the two two-or-more-stage inverter chains.

6. The level shift circuit according to claim 4, further comprising:
an output circuit that outputs a pair of complementary fourth signals, based on the pair of third signals outputted from the precharge control circuit,
wherein the output circuit includes: a second phase alignment circuit that adjusts phases of the pair of complementary fourth signals to be substantially aligned; and two two-or-more-stage inverter chains for generating the pair of complementary fourth signals,
the second phase alignment circuit includes a third P-type MOSFET and a fourth P-type MOSFET,
a source terminal of the third P-type MOSFET and a source terminal of the fourth P-type MOSFET are connected to the second voltage source,
a gate terminal of the third P-type MOSFET is connected to a drain terminal of the fourth P-type MOSFET, and a gate terminal of the fourth P-type MOSFET is connected to a drain terminal of the third P-type MOSFET, and
the drain terminal of the third P-type MOSFET is connected to an input terminal of a final-stage inverter included in one of the two two-or-more-stage inverter chains, and the drain terminal of the fourth P-type MOSFET is connected to an input terminal of a final-stage inverter included in an other of the two two-or-more-stage inverter chains.

7. The level shift circuit according to claim 6,
wherein the first transistor is a first N-type MOSFET and the second transistor is a second N-type MOSFET,
a gate terminal of the first N-type MOSFET is connected to an output terminal of the final-stage inverter included in the two-or-more-stage inverter chain, and a gate terminal of the second N-type MOSFET is connected to an output terminal of the final-stage inverter included in the one-stage transfer gate and the one-or-more-stage inverter chain,
a drain terminal of the first N-type MOSFET is connected to the first node, and a drain terminal of the second N-type MOSFET is connected to the second node,
the precharge circuit further includes a third N-type MOSFET, a fourth N-type MOSFET, a fifth P-type MOSFET, and a sixth P-type MOSFET,
a source terminal of the third N-type MOSFET and a source terminal of the fourth N-type MOSFET are grounded,
a drain terminal of the third N-type MOSFET is connected to a source terminal of the first transistor, and a drain terminal of the fourth N-type MOSFET is connected to a source terminal of the second transistor,
a source terminal of the fifth P-type MOSFET and a source terminal of the sixth P-type MOSFET are connected to the second voltage source,
a drain terminal of the fifth P-type MOSFET is connected to a drain terminal of the first transistor, and a drain terminal of the sixth P-type MOSFET is connected to a drain terminal of the second transistor,
the precharge control circuit includes a set-reset flip-flop circuit,
the first node and the second node are each connected to an input terminal of the set-reset flip-flop circuit,
one of two output terminals of the precharge control circuit is connected to the gate terminal of the third N-type MOSFET and the gate terminal of the fifth P-type MOSFET, and an other of the two output terminals of the precharge control circuit is connected to the gate terminal of the fourth N-type MOSFET and the gate terminal of the sixth P-type MOSFET, the third N-type MOSFET, the fourth N-type MOSFET, the fifth P-type MOSFET, and the sixth P-type MOSFET being included in the precharge circuit,
the set-reset flip-flop circuit is set due to a transition to a low potential at the first node, and the first node is connected to the second voltage source by the setting of the set-reset flip-flop circuit, and
the set-reset flip-flop circuit is reset due to a transition to a low potential at the second node, and the second node is connected to the second voltage source by the resetting of the set-reset flip-flop circuit.

8. The level shift circuit according to claim 7,
wherein the precharge circuit further includes a seventh P-type MOSFET,
a drain terminal is connected to the first node, and a source terminal of the seventh P-type MOSFET is connected to the second node, and a gate terminal of the seventh P-type MOSFET is grounded.

9. The level shift circuit according to claim 7,
wherein the precharge circuit further includes an eighth P-type MOSFET and a ninth P-type MOSFET,
a source terminal of the eighth P-type MOSFET and a source terminal of the ninth P-type MOSFET are connected to the second voltage source,
a drain terminal of the eighth P-type MOSFET is connected to the first node,
a gate terminal of the eighth P-type MOSFET is connected to the gate terminal of the second N-type MOSFET,
a drain terminal of the ninth P-type MOSFET is connected to the second node, and
a gate terminal of the ninth P-type MOSFET is connected to the gate terminal of the first N-type MOSFET.

10. The level shift circuit according to claim 7,
wherein the precharge circuit further includes an eighth P-type MOSFET and a ninth P-type MOSFET,
a source terminal of the eighth P-type MOSFET and a source terminal of the ninth P-type MOSFET are connected to the second voltage source,
a drain terminal of the eighth P-type MOSFET is connected to the first node,
a gate terminal of the eighth P-type MOSFET is connected to an input terminal of an inverter including an output terminal connected to the gate terminal of the second N-type MOSFET, among the two-or-more-stage inverter chain, the one-stage transfer gate, and the one-or-more-stage inverter chain included in the input circuit,
a drain terminal of the ninth P-type MOSFET is connected to the second node, and
a gate terminal of the ninth P-type MOSFET is connected to an input terminal of an inverter including an output terminal connected to the gate terminal of the first N-type MOSFET, among the two-or-more-stage inverter chain, the one-stage transfer gate, and the one-or-more-stage inverter chain included in the input circuit.

11. The level shift circuit according to claim 9,
wherein a source-drain current when the eighth P-type MOSFET and the ninth P-type MOSFET are ON is (i) less than 0.1 times a source-drain current when the first N-type MOSFET and the second N-type MOSFET are ON, and (ii) more than 10 times a source-drain current when the first N-type MOSFET and the second N-type MOSFET are OFF.

12. The level shift circuit according to claim 10,
wherein a source-drain current when the eighth P-type MOSFET and the ninth P-type MOSFET are ON is (i) less than 0.1 times a source-drain current when the first N-type MOSFET and the second N-type MOSFET are ON, and (ii) more than 10 times a source-drain current when the first N-type MOSFET and the second N-type MOSFET are OFF.

13. A level shift method that shifts a logic level, the level shift method comprising:
converting an input signal into a pair of complementary first signals, the input signal being generated using a first voltage source as a power source;
outputting a pair of second signals corresponding to the pair of complementary first signals from a first node and a second node after precharging the first node and the second node to an electric potential of a second voltage source, the first node and the second node being included in a precharge circuit;
outputting a pair of third signals and controlling the precharge circuit, based on the pair of second signals outputted in the outputting of the pair of second signals; and
adjusting phases of the pair of complementary first signals and/or the pair of third signals to be substantially aligned.
